(19) United States
(12) Patent Application Publication
(10) Pub. No.: US 2026/0065967 A1
(43) Pub. Date: Mar. 5, 2026

(54) MEMORY PERFORMING TARGET REFRESH OPERATION AND OPERATING METHOD OF MEMORY

(71) Applicant: SK hynix Inc., Gyeonggi-do (KR)

(72) Inventor: Kyung Mook KIM, Gyeonggi-do (KR)

(21) Appl. No.: 18/932,586

(22) Filed: Oct. 30, 2024

(30) Foreign Application Priority Data
Aug. 27, 2024 (KR) 10-2024-0115357

(51) Int. Cl. G11C 11/406; G11C 11/4096

(52) U.S. Cl. CPC G11C 11/40622; G11C 11/40615; G11C 11/4096

(57) ABSTRACT

A memory may include a cell array including memory cells arranged in a plurality of rows and a plurality of columns, and a refresh target selection circuit configured to select a target row for a target refresh operation based on a quantity of active operations for each row in the cell array and an error history for each row.

### CROSS-REFERENCE TO RELATED APPLICATION(S)

This application claims priority under 35 U.S.C. § 119 to Korean Patent Application No. 10-2024-0115357, filed on Aug. 27, 2024, the disclosure of which is incorporated herein by reference in its entirety.

### BACKGROUND

### 1. Technical Field

Various embodiments of the present disclosure relate to a memory.

### 2. Related Art

Volatile memories such as DRAM need a refresh operation (i.e., a normal refresh operation) periodically performed to retain data stored therein. In addition to the normal refresh operation, an additional refresh operation, which will be hereinafter referred to as a “target refresh operation”, is performed on memory cells of a specific row or word line that is likely to lose data due to a row hammering phenomenon. The row hammering phenomenon refers to a phenomenon in which data of memory cells coupled to a specific row or neighboring rows disposed adjacent to the specific row are damaged due to a high quantity of activations (i.e., active operations) of the specific row.

In order to prevent the row hammering phenomenon, a quantity of active operations is counted for each row, and a target refresh operation is performed on a row that is activated more than a predetermined number of times, and neighboring rows disposed adjacent to the row.

### SUMMARY

In accordance with an embodiment of the present disclosure, a memory may include a cell array including memory cells arranged in a plurality of rows and a plurality of columns; and a refresh target selection circuit configured to select a target row for a target refresh operation based on a quantity of active operations for each row in the cell array and an error history for each row.

In accordance with an embodiment of the present disclosure, a memory may include a normal cell region including normal memory cells arranged in a plurality of rows and a plurality of columns; an access count cell region including access count memory cells arranged in a same quantity of rows as the normal cell region and a different quantity of columns than the normal cell region, and configured to store an error history for each row and a quantity of active operations for each row; and a refresh target selection circuit configured to select a target row for a target refresh operation based on the error history for each row and the quantity of active operations for each row stored in the access count cell region.

In accordance with an embodiment of the present disclosure, a method for performing an error check operation of a memory may include activating a first row in a cell array; reading data of selected memory cells of the first row; detecting an error in the data to correct the detected error; writing error-corrected data to the selected memory cells of the first row; writing a detection history of the error to a predetermined memory cell of the first row; and pre-charging the first row.

In accordance with an embodiment of the present disclosure, an operating method of a memory may include selecting a target row for a target refresh operation based on a quantity of active operations for each row in a cell array and an error history for each row; receiving a refresh management command; and refreshing the refresh target row in response to the refresh management command.

### BRIEF DESCRIPTION OF THE DRAWINGS

FIG. 1 is a block diagram illustrating a memory system in accordance with an embodiment of the present disclosure.

FIG. 2 is a block diagram illustrating a memory illustrated in FIG. 1, in accordance with an embodiment of the present disclosure.

FIG. 3 is a diagram illustrating scoring of rows by a refresh target selection circuit, in accordance with an embodiment of the present disclosure.

FIG. 4 is a flowchart illustrating an error check operation in accordance with an embodiment of the present disclosure.

### DETAILED DESCRIPTION

Various embodiments of the present disclosure are directed to technology of reducing errors in a memory.

According to embodiments of the present disclosure, it is possible to reduce errors in a memory and increase the reliability of the memory.

Hereinafter, various embodiments according to the technical spirit of the present disclosure are described below with reference to the accompanying drawings.

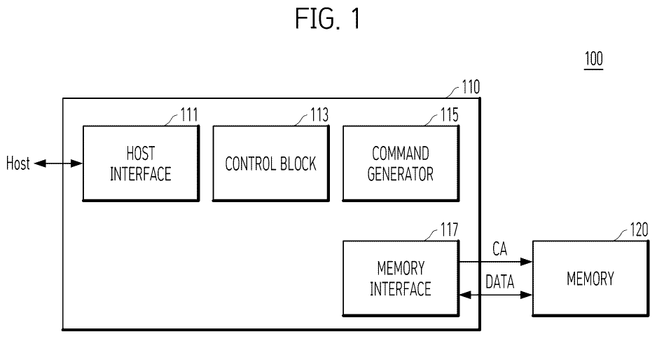

FIG. 1 is a block diagram illustrating a memory system 100 in accordance with an embodiment of the present disclosure.

The memory system 100 may include a memory 120 and a memory controller 110.

The memory controller 110 may control operations of the memory 120 upon a request of a host. The host may include a central processing unit (CPU), a graphic processing unit (GPU), and an application processor (AP). The memory controller 110 may include a host interface 111, a control block 113, a command generator 115, and a memory interface 117. The memory controller 110 may be included in the CPU, GPU, and AP. In this case, the host may denote the configuration other than the memory controller 110 in these configurations. For example, when the memory controller 110 is included in the CPU, the host illustrated in the drawing may represent the constituent elements excluding the memory controller 110 from the CPU.

The host interface 111 may be an interface for communication between the host and the memory controller 110.

The control block 113 may control overall operation of the memory controller 110 and schedule operations to be directed to the memory 120. The control block 113 may change the order in which requests are received from the host and the order of operations to be directed to the memory 120, in order to improve the performance of the memory 120. For example, even though the host requests a read operation of the memory 120 first and requests a write operation later, the order may be adjusted so that the write operation is performed before the read operation.

The command generator 115 may generate a command to be applied to the memory 120 according to the order of operations which is determined by the control block 113.

The memory interface 117 may be for an interface between the memory controller 110 and the memory 120. A command and address CA may be transmitted from the memory controller 110 to the memory 120 through the memory interface 117, and data DATA may be transmitted/received through the memory interface 117. The memory interface 117 may also be referred to as a PHY interface.

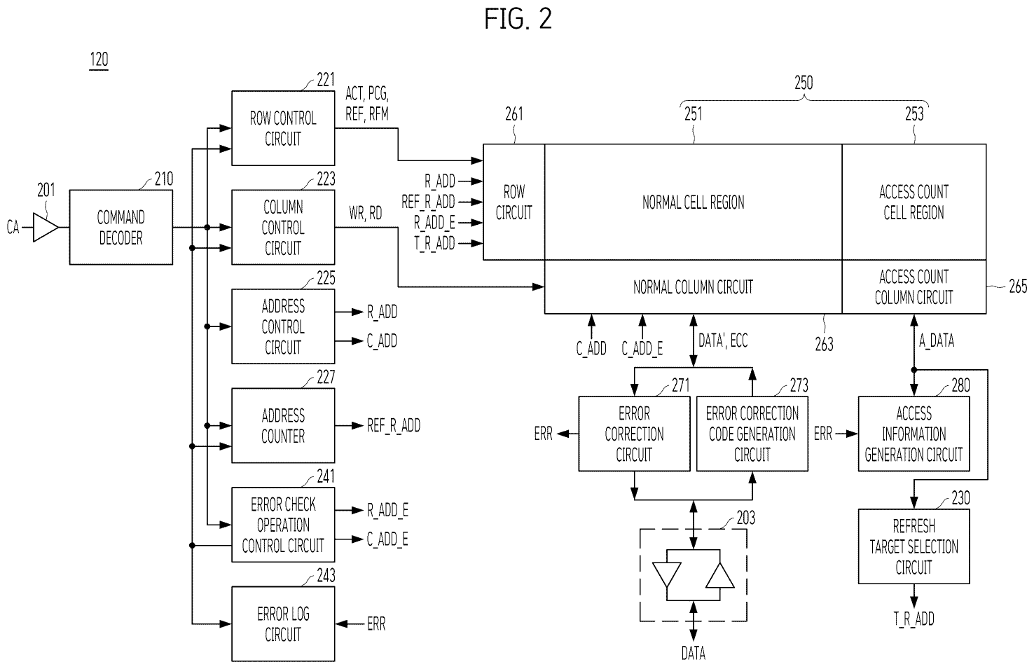

The memory 120 may perform an operation directed by the memory controller 110. The memory 120 is described in detail below with reference to FIG. 2.

FIG. 2 is a block diagram illustrating the memory 120 illustrated in FIG. 1, in accordance with an embodiment of the present disclosure.

Referring to FIG. 2, the memory 120 may include a command address receiving circuit 201, a data transmitting/receiving circuit 203, a command decoder 210, a row control circuit 221, a column control circuit 223, an address control circuit 225, an address counter 227, a refresh target selection circuit 230, an error check operation control circuit 241, an error log circuit 243, a cell array 250, a row circuit 261, a normal column circuit 263, an access count column circuit 265, an error correction circuit 271, an error correction code generation circuit 273, and an access information generation circuit 280.

The command address receiving circuit 201 may receive the command and address CA. Depending on standards of the memory 120, the command and address CA may be inputted to the same input terminals, or the command and address CA may be inputted to separate input terminals. In an embodiment, an example in which the command and address CA are inputted to the same input terminals is described. The command and address CA may have multi-bits.

The data transmitting/receiving circuit 203 may receive the data DATA or transmit the data DATA. The data transmitting/receiving circuit 203 may receive the data DATA to be written to the cell array 250 during the write operation, and transmit the data DATA read from the cell array 250 during the read operation.

The command decoder 210 may decode the command and address CA to find out the type of operations directed by the memory controller 110 to the memory 120.

When a row operation such as an active operation, a pre-charge operation and a refresh operation is directed as a result of the decoding of the command decoder 210, the row control circuit 221 may control these operations. An active signal ACT is a signal directing the active operation, a pre-charge signal PCG is a signal directing the pre-charge operation, and a refresh signal REF is a signal directing the refresh operation. In addition, a refresh management signal RFM may be a signal directing a refresh management operation. The refresh management operation may be an operation for refreshing a target row selected by the refresh target selection circuit 230 to prevent data loss due to a row hammer attack. This operation is also referred to as a target refresh operation or a smart refresh operation.

When a column-based operation such as the write operation and the read operation is directed as a result of the decoding of the command decoder 210, the column control circuit 223 may control these operations. A write signal WR is a signal directing the write operation, and a read signal RD is a signal directing the read operation.

The address control circuit 225 may classify an address received from the command decoder 210 into a row address R_ADD and a column address C_ADD and transmit the row address R_ADD and the column address C_ADD to the row circuit 261 and the normal column circuit 263, respectively. The address control circuit 225 may classify the received address into the row address R_ADD when the active operation is directed based on a result of the decoding of the command decoder 210, and may classify the received address into the column address C_ADD when the read and write operations are directed based on the result of the decoding of the command decoder 210.

The address counter 227 may generate a refresh address REF_R_ADD to be used during the refresh operation. The address counter 227 may change the refresh address REF_R_ADD by +1 whenever the refresh signal REF is activated. Because the refresh address REF_R_ADD is changed whenever the refresh signal REF is activated, all rows in the cell array 250 may be sequentially refreshed.

The cell array 250 may include memory cells arranged in a plurality of rows and a plurality of columns. The cell array 250 may include a normal cell region 251 and an access count cell region 253. The normal cell region 251 is a region that stores write data and provides the stored data as read data. The access count cell region 253 is a region that stores a quantity of active operations for each row and an error history for each row. The normal cell region 251 and the access count cell region 253 may share the rows.

The row circuit 261 may control the rows in the cell array 250. When the active signal ACT is activated, the row circuit 261 may activate a row selected by the row address R_ADD among the rows in the cell array 250. During an error check operation, the row circuit 261 may activate a row selected by an error check row address R_ADD_E among the rows in the cell array 250 when the active signal ACT is activated. The row circuit 261 may pre-charge the activated row when the pre-charge signal PCG is activated. When the refresh signal REF is activated, the row circuit 261 may refresh a row selected by the refresh address REF_R_ADD among the rows in the cell array 250. In addition, the row circuit 261 may refresh a row corresponding to a target row address T_R_ADD among the rows in the cell array 250 when the refresh management signal RFM is activated.

The normal column circuit 263 may write data DATA′ and an error correction code ECC to columns selected by the column address C_ADD among columns in the normal cell region 251 during the write operation, that is, to memory cells corresponding to the activated row and the selected columns. In addition, the normal column circuit 263 may read the data DATA′ and the error correction code ECC from the columns selected by the column address C_ADD among the columns in the normal cell region 251 during the read operation. The normal column circuit 263 may use an error check column address C_ADD_E instead of the column address C_ADD during the error check operation.

During the pre-charge operation, the access count column circuit 265 may read access data A_DATA from columns in the access count cell region 253, that is, from columns in the access count cell region 253 coupled to the activated row, and transmit the access data A_DATA to the access information generation circuit 280. In addition, when the access information generation circuit 280 updates the access data A_DATA, the access count column circuit 265 writes again the updated data to the columns in the access count cell region 253, that is, to memory cells of the access count cell region 253 coupled to the activated row. Because all columns are accessed when the access count cell region 253 is accessed, the access count column circuit 265 may not use the column address C_ADD.

The access information generation circuit 280 may update the access data A_DATA transmitted from the access count column circuit 265. The access data A_DATA includes the quantity of active operations for each row and the error history for each row. For example, when the access data A_DATA has 10 bits, 9 bits of the 10 bits may be used to record the quantity of active operations, and 1 bit of the 10 bits may be used to record the error history. The access information generation circuit 280 may increase the quantity of active operations of the access data A_DATA by +1 whenever the pre-charge operation is performed. In addition, the access information generation circuit 280 may record error history information of the access data A_DATA as “1” when an error is found in a corresponding row during the error check operation. When the error history information is “0”, it may mean that no error is found in the corresponding row, and when the error history information is “1”, it may mean that an error is found in the corresponding row.

The error correction code generation circuit 273 may generate the error correction code ECC using the data DATA during the write operation. During the write operation, the error correction code ECC may be generated using the data DATA, but an error in the data DATA may not be corrected. Accordingly, the data DATA inputted to the error correction code generation circuit 273 may be the same as the data DATA outputted from the error correction code generation circuit 273.

The error correction circuit 271 may correct an error in the data DATA′ read by the normal column circuit 263 using the error correction code ECC read by the normal column circuit 263 during the read operation. The correcting of the error may represent detecting the error in the data DATA′ and correcting the error in the data DATA′ when the error is found. The error correction circuit 271 may also detect and correct an error in the error correction code ECC together with the data DATA′. When the error in the data DATA′ is found and corrected, the data DATA′ inputted to the error correction circuit 271 may be different from the data DATA outputted from the error correction circuit 271. An error signal ERR may be a signal that is activated when an error is found by the error correction circuit 271.

The error check operation control circuit 241 may control the error check operation of the memory 120. When the setting of an error check operation mode is directed by the memory controller 110 as a result of the decoding of the command decoder 210, the memory 120 may operate in the error check operation mode, and may operate under the control of the error check operation control circuit 241 in the error check operation mode. The error check operation, which is also referred to as an error check and scrub (ECS) operation, may be an operation of reading the data DATA′ and the error correction code ECC from the normal cell region 251 of the cell array 250, checking the error in the data DATA′ using the error correction circuit 271, and logging a history of the error into the error log circuit 243. The error check operation control circuit 241 may control the error check operation when the error check operation mode is set. Because a row operation and a column operation need to be controlled during the error check operation, the error check operation control circuit 241 may control the row control circuit 221 and the column control circuit 223 during the error check operation. In addition, the error check operation control circuit 241 may control the error log circuit 243 related to the error check operation.

The error check operation control circuit 241 may generate the error check addresses R_ADD_E and C_ADD_E to be used for the error check operation. The error check addresses R_ADD_E and C_ADD_E may include the error check row address R_ADD_E and the error check column address C_ADD_E. The error check operation control circuit 241 may increase the error check addresses R_ADD_E and C_ADD_E by 1 step whenever the error check operation is performed. When a value of the error check row address R_ADD_E ranges from 0 to X and a value of the error check column address C_ADD_E ranges from 0 to Y, the error check operation control circuit 241 may generate the error check addresses R_ADD_E and C_ADD_E as (0,0) during a first error check and scrub operation. During a second error check and scrub operation, the error check operation control circuit 241 may increase the error check addresses R_ADD_E and C_ADD_E by 1 step and generate the error check addresses R_ADD_E and C_ADD_E as (0,1). Similarly, during a third error check and scrub operation, the error check operation control circuit 241 may increase the error check addresses R_ADD_E and C_ADD_E by 1 step again and generate the error check addresses R_ADD_E and C_ADD_E as (0,2). The error check addresses R_ADD_E and C_ADD_E may increase by 1 step for each error check and scrub operation and be generated differently each time, such as (0,0)->(0,1)->(0,2)->. . . ->(0,Y-1)->(0,Y)->(1,0)->(1,1)->. . . ->(1,Y-1)->(1,Y)->(2,0)->(2,1)->. . . ->(X, Y-1)->(X, Y). Because the error check operation control circuit 241 changes the error check addresses R_ADD_E and C_ADD_E whenever the error check and scrub operations are performed, the error check operation may be performed on all memory cells in the normal cell region 251 of the cell array 250 when the error check and scrub operations are repeatedly performed.

The refresh target selection circuit 230 may select a target row for a target refresh operation using the quantity of active operations for each row and the error history for each row. The target row address T_R_ADD is an address of the target row selected by the refresh target selection circuit 230. When the access information generation circuit 280 updates the access data A_DATA, the refresh target selection circuit 230 may receive the access data A_DATA and select the target row using the access data A_DATA. The refresh target selection circuit 230 may assign scores to an (N−1)^{th} row and an (N+1)^{th} row according to a quantity of activations of an N^{th} row, calculate a score for each row by assigning a weighted score to the N^{th} row according to an error history of the N^{th} row, and select a row with a higher score among the rows as the target row. For example, the quantity of activations of the N^{th} row may increase the scores of the (N−1)^{th} row and (N+1)^{th} row by 1 point each time, and the error history of the N^{th} row may increase the score of the N^{th} row by 300 points.

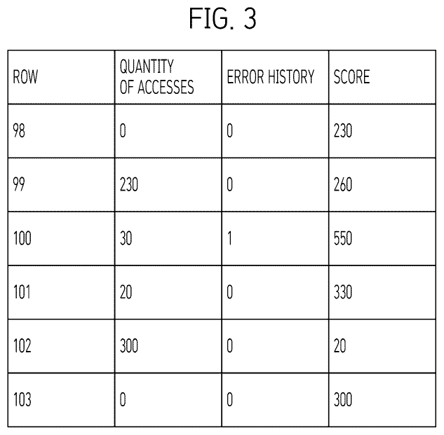

FIG. 3 illustrates that the refresh target selection circuit 230 assigns scores to 98^{th} to 103^{rd} rows, in accordance with an embodiment of the present disclosure. Referring to FIG. 3, a result of assigning the scores to the 98^{th} to 103^{rd} rows by considering a quantity of activations of neighboring rows and an error history of a corresponding row may indicate that the highest score is assigned to a 100^{th} row. In this case, the refresh target selection circuit 230 may select the 100^{th} row as the target row. The higher the quantity of activations of the neighboring rows, the higher the possibility of an error occurring due to row hammering, and the presence of the error history of the corresponding row may represent that the possibility of an error occurring in the corresponding row is high. Therefore, a target row selection operation in this manner may be performed. In the above example, it is described that a weight of 300 points is assigned to the error history, but this is merely an example, and it is apparent that the number of the weight may be changed.

The error log circuit 243 may log the error found during the error check operation. An error log history collected in the error log circuit 243 may be transmitted from the memory 120 to the memory controller 110 upon a request of the memory controller 110.

In an embodiment, the error history for each row is stored together with the quantity of activations for each row in the access count cell region 253 of the cell array 250, and the refresh target selection circuit 230 uses the error history for each row and the quantity of activations for each row stored in the access count cell region 253. Alternatively, the error history for each row may be stored in the error log circuit 243, and the quantity of activations for each row may be stored in the access count cell region 253, so that the refresh target selection circuit 230 may select the target row using the information stored in the error log circuit 243 and the access count cell region 253.

### Active Operation

The active operation may be an operation of activating a row. During the active operation, the row circuit 261 may activate the row selected by the row address R_ADD among the rows in the cell array 250. Because the normal cell region 251 and access count cell region 253 of the cell array 250 share the rows, the normal cell region 251 and the access count cell region 253 may be activated simultaneously. During the active operation, data of the memory cells of the selected row may be detected and amplified.

### Write Operation

The write operation may be performed during the active operation. For example, when a 10^{th} row is in an active state, the write operation may be performed on the 10^{th} row. During the write operation, the data transmitting/receiving circuit 203 may receive the data DATA, and the error correction code generation circuit 273 may generate the error correction code ECC using the data DATA. The normal column circuit 263 may write the data DATA′ and the error correction code ECC to the columns selected by the column address C_ADD among the columns in the normal cell region 251. That is, the data DATA′ and the error correction code ECC may be written to the memory cells of the row activated by the row circuit 261 and the columns selected by the normal column circuit 263.

### Read Operation

The read operation may be performed during the active operation. For example, when a third row is in an active state, the read operation may be performed on the third row. During the read operation, the normal column circuit 263 may read the data DATA′ and the error correction code ECC from the columns selected by the column address C_ADD among the columns in the normal cell region 251. That is, the data DATA′ and the error correction code ECC may be read from the memory cells of the row activated by the row circuit 261 and the columns selected by the normal column circuit 263. The data DATA′ and error correction code ECC read by the normal column circuit 263 may be transmitted to the error correction circuit 271, and the data DATA whose error is corrected by the error correction circuit 271 may be outputted by the data transmitting/receiving circuit 203.

### Pre-Charge Operation

The pre-charge operation is an operation of terminating the active operation. However, when a pre-charge command is applied to the memory 120, an operation of counting the quantity of activations for each row may be performed, and then an operation of pre-charging the row may be performed. That is, the pre-charge operation may be performed in the following order: (1) receiving, by the memory 120, the pre-charge command, (2) reading, by the access count column circuit 265, the access data A_DATA from the access count cell region 253, (3) updating, by the access information generation circuit 280, the access data A_DATA, (4) writing, by the access count column circuit 265, the updated access data A_DATA to the access count cell region 253, and (5) pre-charging or deactivating, by the row circuit 261, the activated row or word line.

### Refresh Operation

During the refresh operation in which the refresh signal REF is activated, the row circuit 261 may refresh a row corresponding to the refresh address REF_R_ADD among the rows in the cell array 250. The “refresh” may mean activating and then pre-charging the corresponding row. During the active operation, data of the memory cells of the corresponding row may be detected, amplified, i.e., rewritten, and pre-charged.

During the target refresh operation in which the refresh management signal RFM is activated, the row circuit 261 may refresh a row corresponding to the target row address T_R_ADD among the rows in the cell array 250. Accordingly, a target row selected by the refresh target selection circuit 230, that is, a row with a high possibility of error occurrence, may be refreshed.

### Error Check Operation

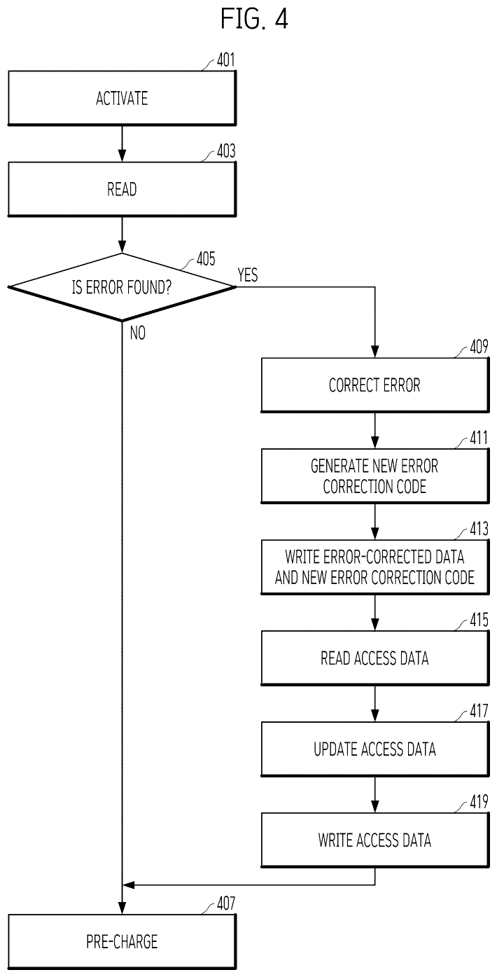

The error check operation may be performed under the control of the error check operation control circuit 241. FIG. 4 illustrates the error check operation, which is described below with reference to FIG. 4.

First, the active operation may be performed in operation 401. The row circuit 261 may activate a row corresponding to the error check row address R_ADD_E among the rows in the cell array 250.

Subsequently, the read operation may be performed in operation 403. The normal column circuit 263 may read the data DATA′ and the error correction code ECC from columns corresponding to the error check column address C_ADD_E among the columns in the normal cell region 251 and transmit the data DATA′ and the error correction code ECC to the error correction circuit 271. That is, the data DATA′ and the error correction code ECC may be read from memory cells selected by the error check row address R_ADD_E and the error check column address C_ADD_E and transmitted to the error correction circuit 271.

When a result of the operation of the error correction circuit 271 indicates that no error is found (that is, “N” in operation 405), the row activated in the operation 401 may be pre-charged in operation 407.

When the result of the operation of the error correction circuit 271 indicates that an error is found (that is, “Y” in the operation 405), the error may be corrected by the error correction circuit 271 in operation 409, and the error correction code generation circuit 273 may generate a new error correction code ECC using the data DATA whose error is corrected, in operation 411. Then, in operation 413, the error-corrected data DATA and the new error correction code ECC may be written again to the memory cells on which the read operation was performed in the operation 403.

Subsequently, the access count column circuit 265 may read the access data A_DATA from the memory cells of the activated row in the access count cell region 253 and transfer the access data A_DATA to the access information generation circuit 280, in operation 415. The access information generation circuit 280 may update the error history of the access data A_DATA for each row to “1” in operation 417. Then, the updated access data A_DATA may be written again to the access count cell region 253 in operation 419. Because the error history for each row is completely updated, the activated row may be pre-charged in the operation 407.

In the error check operation mode, the operations of FIG. 4 may be repeatedly performed while changing the error check addresses R_ADD_E and C_ADD_E.

The access data A_DATA stored in the access count cell region 253 of the cell array 250 may be initialized periodically. The quantity of active operations for each row in the access data A_DATA is information that no longer needs to be considered once the refresh operation is performed. The quantity of active operations for each row is information for recording that the active operation is performed excessively multiple times between refresh operation periods. A length of a refresh period in which all memory cells in the memory 120 are refreshed once is 1 second or less. Therefore, the quantity of active operations for each row in the access data A_DATA may be initialized in a period of 1 second or less.

The error history for each row in the access data A_DATA is information collected in an extremely long period. For example, it may take approximately 24 hours for the error history of all memory cells to be collected through the error check operation in the memory 120. Therefore, the error history for each row in the access data A_DATA may not be initialized, or may be initialized in a period of 24 hours or more even though the error history for each row in the access data A_DATA is initialized.

According to embodiments described above, the target refresh operation may be performed not only on rows affected by row hammering but also on rows each having an error history. As the target refresh operation is performed, it is possible to protect data of memory cells attacked by the row hammering and memory cells each having an error history. Consequently, it is possible to reduce an error in the memory.

Although the Technical Spirit of the Present Disclosure Has Been described above according to embodiments, this is only for describing the embodiments according to the concept of the present disclosure, and the present disclosure is not limited to the above embodiments. Various embodiments may be applied by those skilled in the art, to which the present disclosure pertains, within the scope of the technical spirit of the present disclosure. Furthermore, the embodiments may be combined to form additional embodiments.

What is claimed is:

1. A memory comprising:
a cell array including memory cells arranged in a plurality of rows and a plurality of columns; and
a refresh target selection circuit configured to select a target row for a target refresh operation based on a quantity of active operations for each row in the cell array and an error history for each row.

2. The memory of claim 1, wherein the error history for each row includes information collected during an error check operation of the memory.

3. The memory of claim 1, wherein the cell array includes:
a normal cell region configured to store data; and
an access count cell region configured to store the quantity of active operations for each row.

4. The memory of claim 3, wherein the access count cell region is further configured to store the error history for each row.

5. The memory of claim 4, wherein the quantity of active operations for each row stored in the access count cell region is periodically initialized, and an initialization period of the error history for each row is longer than an initialization period of the quantity of active operations for each row.

6. The memory of claim 3, further comprising an error log circuit configured to store the error history for each row.

7. The memory of claim 1, wherein when a refresh management command is applied, the target row in the cell array is refreshed.

8. A memory comprising:
a normal cell region including normal memory cells arranged in a plurality of rows and a plurality of columns;
an access count cell region including access count memory cells arranged in a same quantity of rows as the normal cell region and a different quantity of columns than the normal cell region, and configured to store an error history for each row and a quantity of active operations for each row; and
a refresh target selection circuit configured to select a target row for a target refresh operation based on the error history for each row and the quantity of active operations for each row stored in the access count cell region.

9. The memory of claim 8, further comprising an error correction circuit configured to detect and correct an error in data read from the normal cell region,
wherein the error history for each row is generated based on the error detected by the error correction circuit.

10. The memory of claim 8, wherein the error history for each row includes information collected during an error check operation of the memory.

11. The memory of claim 8, wherein the quantity of active operations for each row stored in the access count cell region is periodically initialized, and an initialization period of the error history for each row is longer than an initialization period of the quantity of active operations for each row.

12. The memory of claim 8, wherein when a refresh management command is applied, the target row in the cell array is refreshed.

13. A method for performing an error check operation of a memory, the method comprising:
activating a first row in a cell array;
reading data of selected memory cells of the first row;
detecting an error in the data to correct the detected error;
writing error-corrected data to the selected memory cells of the first row;
writing a detection history of the error to a predetermined memory cell of the first row; and
pre-charging the first row.

14. The method of claim 13, further comprising:
activating a second row in the cell array;
reading data of selected memory cells of the second row;
checking that no error is present in the read data; and
pre-charging the second row.

15. An operating method of a memory, the operating method comprising:
selecting a target row for a target refresh operation based on a quantity of active operations for each row in a cell array and an error history for each row;
receiving a refresh management command; and
refreshing the target row in response to the refresh management command.

16. The operating method of claim 15, wherein the error history for each row includes information collected during an error check operation of the memory.

17. The operating method of claim 15, further comprising:
periodically initializing the quantity of active operations for each row; and
periodically initializing an initialization period of the error history,
wherein an initialization period of the error history for each row is longer than an initialization period of the quantity of active operations for each row.
